(19) United States
(12) Patent Application Publication
(10) Pub. No.: US 2019/0178946 A1
(43) Pub. Date: Jun. 13, 2019

(54) BATTERY CLASSIFICATION METHOD AND SYSTEM

(71) Applicant: Beijing Chuangyu Technology Co., Ltd., Beijing (CN)

(72) Inventors: Yanchuan Han, Beijing (CN); Ang Zhao, Beijing (CN); Yapei Jia, Beijing (CN); Songli Liu, Beijing (CN)

(21) Appl. No.: 16/120,145

(22) Filed: Aug. 31, 2018

(30) Foreign Application Priority Data
Dec. 13, 2017 (CN) 201711328857.6

(51) Int. Cl. G01R 31/36

(52) U.S. Cl. CPC G01R 31/3651; G01R 31/3662

(57) ABSTRACT

The embodiments of the present disclosure provide a battery classification method and system. The methods includes obtaining circulatory charge and discharge data of a battery pack to be classified, extracting a characteristic data set of the battery pack from the charge and discharge data; reducing the characteristic data set with rough set theory to obtain a reduced characteristic data set of the battery pack; and classifying single batteries of the battery pack according to the reduced characteristic data set with fuzzy clustering algorithm. The battery classification method and system provided by the embodiments of the present disclosure can be applied to the retired power batteries, and improves the efficiency of classifying the retired power batteries.

### CLAIM OF PRIORITY

This application claims priority to Chinese Patent Application No. 201711328857.6, filed Dec. 13, 2017, the entire contents of which are fully incorporated herein by reference.

### TECHNICAL FIELD

The embodiments of the present disclosure relate to the technical field of battery management, and particularly to a battery classification method and system.

### BACKGROUND

Battery energy storage has been playing an important role in various aspects of power generation, power transmission, power transformation, power distribution and power consumption of power systems and has become an indispensable part of smart grid construction since our country put forward the plan of building smart grid in 2009. At present, the cost of battery investment in the construction cost of battery energy storage system is relatively high, accounting for more than 70% of the total investment. It has become a restraint limiting the large-scale application of the battery energy storage.

According to relevant statistics in China, the number of pure electric vehicles has reached to 332,000 in 2015, and it is estimated that the number of used power batteries will reach to 120-170thousandtons in 2020. A power battery for vehicle will be retired when the capacity is less than 80%. However, the batteries retired from the vehicles still have high value of use, it will cause serious waste of resources if they are directly scraped and recycled.

The effective cascade utilization of vehicle power batteries for battery energy storage systems can not only reduce the investment cost of the energy storage systems, but also effectively reduce the cost of using the vehicle power batteries, which saves energy, and has a positive effect on promoting the development of the entire energy storage industry chain.

However, the vehicle power batteries of cascade utilization need to be dismantled, tested, classified, and recombined before being used. The consistency is worse than that of the new vehicle batteries, and a single battery in the battery box has characteristics tend to be more discrete, such as capacity, internal resistance, and power etc. It will cost a great deal of time, manpower, and material resources to classify the batteries according to the characteristics above.

### SUMMARY

With respect to the defects existed in the prior art, the embodiments of the present disclosure provide a battery classification method and system.

In one respect, the embodiments of the present disclosure provide a battery classification method, including:

obtaining circulatory charge and discharge data of a battery pack to be classified, extracting a characteristic data set of the battery pack from the charge and discharge data;

reducing the characteristic data set with rough set theory to obtain a reduced characteristic data set of the battery pack;

classifying single batteries of the battery pack according to the reduced characteristic data set with fuzzy clustering algorithm.

In another respect, the embodiments of the present disclosure provide a battery classification device, including:

at least one processor; at least one memory; an obtaining module, a reducing module and a clustering module stored in the memory, when being executed by the processor,

the obtaining module is configured to obtain circulatory charge and discharge data of a battery pack to be classified, extract a characteristic data set of the battery pack from the charge and discharge data;

the reducing module is configured to reduce the characteristic data set with rough set theory to obtain a reduced characteristic data set of the battery pack;

the clustering module is configured to classify single batteries of the battery pack according to the reduced characteristic data set with fuzzy clustering algorithm.

In another respect, the embodiments of the present disclosure provide an electronic device, including a processor and a memory, wherein the processor and the memory communicate with each other through a bus; the memory stores program instructions executed by the processor, the processor calls the program instructions to execute the battery classification methods above.

In another respect, the embodiments of the present disclosure further provide a computer readable storage medium in which computer programs are stored, the battery classification methods above are implemented when a processor executes the computer programs.

The battery classification method and system provided by the embodiments of the present disclosure can be applied to the retired power batteries, and improves the efficiency of classifying the retired power batteries by obtaining circulatory charge and discharge data of a battery pack to be classified, extracting a characteristic data set of the battery pack from the charge and discharge data; reducing the characteristic data set with rough set theory to obtain a reduced characteristic data set of the battery pack; and classifying single batteries of the battery pack according to the reduced characteristic data set with fuzzy clustering algorithm.

### BRIEF DESCRIPTION OF THE DRAWINGS

In order to more clearly describe the embodiments of the present disclosure or the technical solutions in the prior art, the drawings to be used in describing the embodiments or the prior art will be briefly described below, obviously, the drawings in the following description are some embodiments of the present disclosure, for those of ordinary skill in the art, other drawings may also be obtained based on these drawings without any creative work.

FIG. 1 is a flow chart of the battery classification method provided by an embodiment of the present disclosure;

FIG. 2 is a structural diagram of the battery classification system provided by an embodiment of the present disclosure;

FIG. 3 is a structural diagram of the electronic device provided by an embodiment of the present disclosure;

FIG. 4 is a schematic diagram of the charge and discharge curve of a lithium iron phosphate battery pack provided by an embodiment of the present disclosure;

FIG. 5 is a distribution chart of the battery attribute weights of the lithium iron phosphate battery pack provided by an embodiment of the present disclosure;

FIG. 6 is a fuzzy clustering distribution diagram of the lithium iron phosphate battery pack provided by an embodiment of the present disclosure.

### DETAILED DESCRIPTION

In order to make the objectives, technical solutions, and advantages of the embodiments of the present disclosure clearer, the technical solutions of the embodiments of the present disclosure will be described clearly with reference to the accompanying drawings hereinafter. Obviously, the described embodiments are merely some but not all of the embodiments of the present disclosure. On the basis of the embodiments of the present disclosure, all other embodiments obtained by the person of ordinary skill in the art without creative work shall fall within the protection scope of the present disclosure.

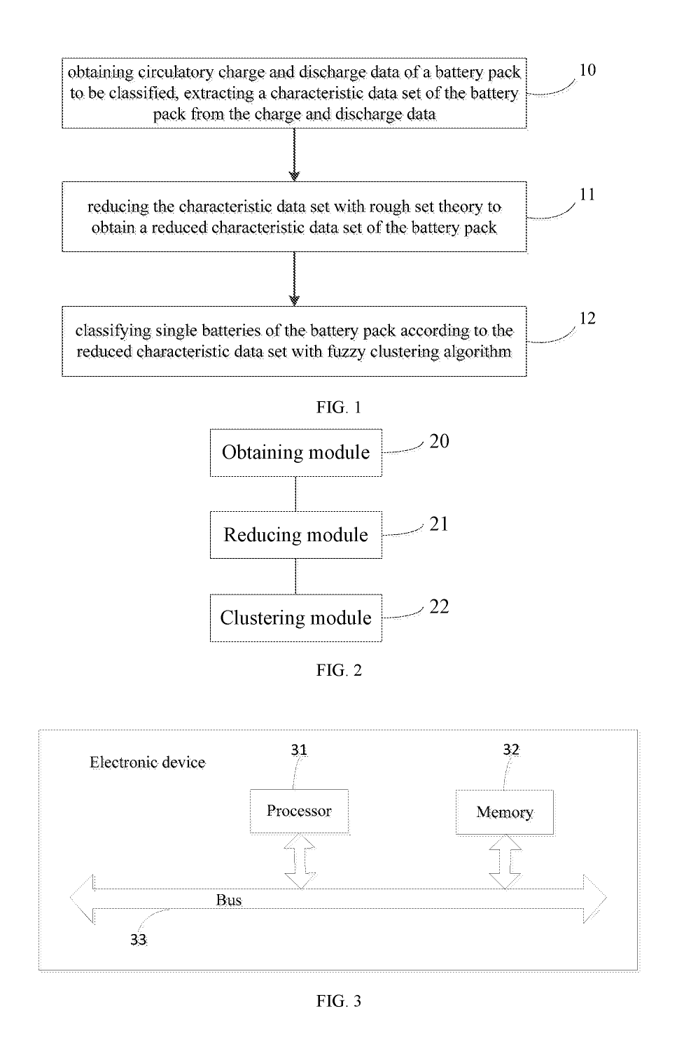

FIG. 1 is a flow chart of the battery classification method provided by an embodiment of the present disclosure, as shown in FIG. 1, the method includes:

Step 10, obtaining circulatory charge and discharge data of a battery pack to be classified, extracting a characteristic data set of the battery pack from the charge and discharge data;

Step 11, reducing the characteristic data set with rough set theory to obtain a reduced characteristic data set of the battery pack;

Step 12, classifying single batteries of the battery pack according to the reduced characteristic data set with fuzzy clustering algorithm.

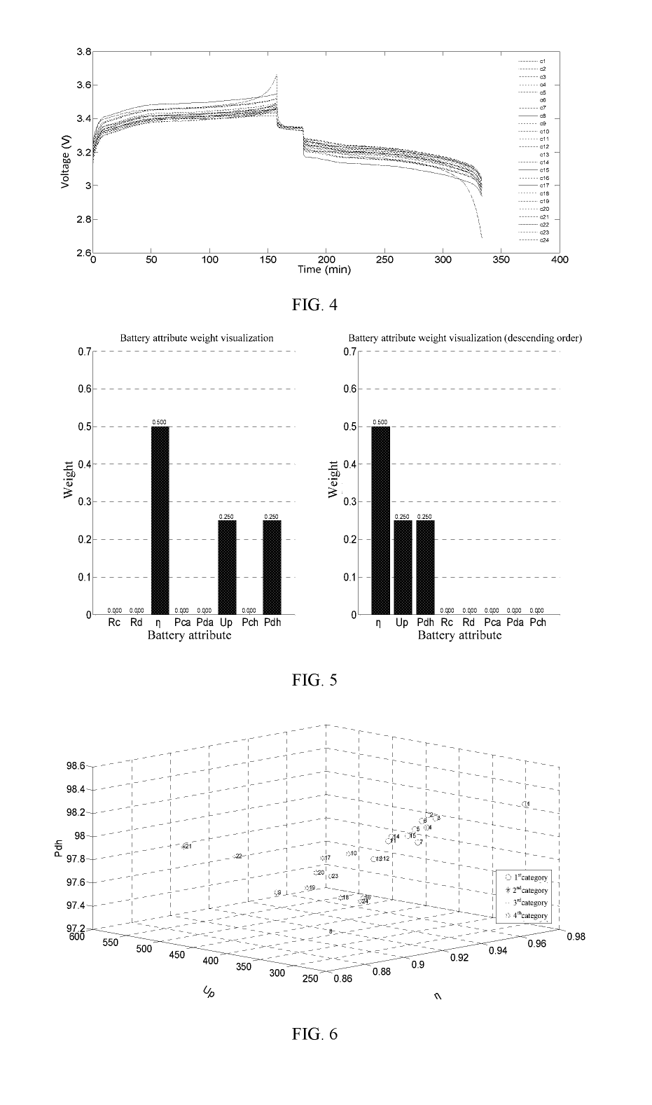

FIG. 4 is a schematic diagram of the charge and discharge curve of a lithium iron phosphate battery pack provided by an embodiment of the present disclosure. Currently, most of the lithium iron phosphate batteries widely used in the field of electric vehicles are connected in series or in parallel by dozens to form a unit module. Whereby, several batteries can reach higher voltages in series so as to drive the motor. Taking 24 100 Ah retired battery packs of a certain model as an example, a charge and discharge test with 0.3 C magnification is conducted, and the test curve is shown in FIG. 4.

Referring to FIG. 4, the voltage discreteness of the 24 lithium iron phosphate batteries is large in the charge and discharge process. The lithium iron phosphate battery with the worst condition reaches the charge and discharge cutoff voltage threshold first, and the charge and discharge curves of several lithium iron phosphate batteries were quite close. It will be difficult to reasonably classify the above-mentioned 24 lithium iron phosphate batteries at a time based on the charge and discharge curve only without special processing.

In the battery classification method provided by the embodiments of the present disclosure, the server may obtain the circulatory charge and discharge data of the battery pack to be classified first, and extract the characteristic data set of the battery pack from the charge and discharge data. For example, the battery pack to be classified includes 24 lithium iron phosphate batteries, the server may obtain the 0.3 C circulatory charge and discharge data of the 24 lithium iron phosphate batteries first, and extract the indicator data characterizing the battery characteristics of the 24 lithium iron phosphate batteries from the 0.3 C circulatory charge and discharge data, so as to form the characteristic data set.

The server may reduce the characteristic data set with the rough set theory, and remove the unimportant indicator data from the characteristic data set, so as to obtain the reduced characteristic data set of the battery pack to be classified.

The server may perform clustering analysis on the reduced characteristic data set, and classify the single batteries of the battery pack with the existing fuzzy clustering algorithm.

The battery classification method provided by the embodiments of the present disclosure can be applied to the retired power batteries, and improves the efficiency of classifying the retired power batteries by obtaining the circulatory charge and discharge data of the battery pack to be classified, extracting the characteristic data set of the battery pack from the charge and discharge data, reducing the characteristic data set with rough set theory to obtain the reduced characteristic data set of the battery pack, and classifying single batteries of the battery pack according to the reduced characteristic data set with fuzzy clustering algorithm.

Alternatively, on the basis of the embodiments above, the characteristic data set includes any combination of the following characteristic data: the charge ohmic resistance, discharge ohmic resistance, energy efficiency, average power of charge, average power of discharge, polarization voltage, temperature, maximum charge power and maximum discharge power of each single battery in the battery pack.

The characteristic data set of the embodiments above includes any combination of the following characteristic data: the charge ohmic resistance, discharge ohmic resistance, energy efficiency, average power of charge, average power of discharge, polarization voltage, temperature, maximum charge power and maximum discharge power of each single battery in the battery pack to be classified.

The technical solutions of the embodiments of the present disclosure will be described in detail hereinafter by taking the battery pack composed of 24 lithium iron phosphate batteries as an example.

The server may extract the characteristic data set of the 24 lithium iron phosphate batteries from the 0.3 C circulatory charge and discharge data of the battery pack composed of 24 lithium iron phosphate batteries, wherein the characteristic data set may include 8 indicator data of each of the 24 lithium iron phosphate batteries, which are respectively: charge ohmic resistance, discharge ohmic resistance, energy efficiency, average power of charge, average power of discharge, polarization voltage, maximum charge power and maximum discharge power.

Wherein the charge ohmic resistance may be denoted as Rc, the discharge ohmic resistance may be denoted as Rd, the energy efficiency may be denoted as the average power of charge may be denoted as Pca, the average power of discharge may be denoted as Pda, the polarization voltage may be denoted as Up, the maximum charge power may be denoted as Pch, and the maximum discharge power may be denoted as Pdh. The characteristic data set of the battery pack composed of 24 lithium iron phosphate batteries is shown in table I, wherein the number of each single battery in the 24 lithium iron phosphate batteries is ranked from 1 to 24 in sequence.

TABLE I

| Battery | R_{c}/ | R_{d}/ | η/ | P_{ca}/ | P_{da}/ | Uₚ/ | P_{ch}/ | P_{dh}/ |
|---|---|---|---|---|---|---|---|---|
| No. | mΩ | mΩ | % | W | W | mV | W | W |
| 1 | 1.21 | 1.45 | 97.83% | 99.38 | 94.87 | 296 | 101.65 | 98.24 |
| 2 | 1.21 | 1.38 | 92.80% | 99.28 | 95.04 | 295 | 101.47 | 98.29 |
| 3 | 1.28 | 1.48 | 93.05% | 99.34 | 94.98 | 291 | 101.47 | 98.26 |
| 4 | 1.70 | 1.78 | 92.94% | 99.65 | 94.68 | 301 | 101.82 | 98.18 |
| 5 | 1.70 | 1.82 | 92.36% | 99.68 | 94.66 | 302 | 101.91 | 98.18 |
| 6 | 1.28 | 1.52 | 92.31% | 99.31 | 95.03 | 290 | 101.44 | 98.26 |
| 7 | 2.06 | 2.12 | 93.03% | 100.02 | 94.35 | 317 | 102.21 | 98.03 |
| 8 | 4.96 | 4.51 | 91.70% | 102.42 | 91.83 | 414 | 104.58 | 97.20 |
| 9 | 3.05 | 3.03 | 87.16% | 100.82 | 93.49 | 358 | 102.95 | 97.73 |
| 10 | 2.41 | 2.46 | 90.14% | 100.36 | 94.00 | 337 | 102.59 | 98.00 |
| 11 | 2.06 | 2.05 | 91.05% | 99.94 | 94.34 | 304 | 102.18 | 98.12 |
| 12 | 2.48 | 2.49 | 91.77% | 100.32 | 93.94 | 335 | 102.50 | 97.91 |
| 13 | 2.41 | 2.49 | 91.03% | 100.31 | 94.09 | 325 | 102.45 | 97.94 |
| 14 | 1.77 | 1.85 | 91.18% | 99.68 | 94.62 | 303 | 101.88 | 98.15 |
| 15 | 1.84 | 1.99 | 92.27% | 99.89 | 94.58 | 310 | 102.00 | 98.12 |
| 16 | 3.97 | 3.70 | 92.04% | 101.56 | 92.82 | 371 | 103.69 | 97.53 |
| 17 | 2.62 | 2.63 | 88.84% | 100.42 | 93.99 | 338 | 102.56 | 98.00 |
| 18 | 3.83 | 3.60 | 90.98% | 101.43 | 92.94 | 373 | 103.60 | 97.56 |
| 19 | 3.83 | 3.64 | 89.08% | 101.44 | 92.90 | 368 | 103.63 | 97.70 |
| 20 | 2.84 | 2.83 | 89.03% | 100.72 | 93.64 | 353 | 102.92 | 97.85 |
| 21 | 4.11 | 4.01 | 90.38% | 101.95 | 92.56 | 591 | 105.46 | 97.79 |
| 22 | 2.27 | 2.93 | 88.26% | 100.38 | 93.80 | 454 | 102.12 | 97.91 |
| 23 | 1.49 | 1.99 | 90.84% | 99.48 | 94.08 | 385 | 101.08 | 97.73 |
| 24 | 2.06 | 2.36 | 91.94% | 99.85 | 93.60 | 372 | 101.53 | 97.50 |

The server may reduce the characteristic data set above with the rough set theory, and remove the unimportant indicator data from the characteristic data set, so as to obtain the reduced characteristic data set of the battery pack to be classified. For example, if three indicator data of energy efficiency, average power of charge and average power of discharge are found to have few influence or no influence on battery classification when the server is reducing the characteristic data set with the rough set theory, the server may remove the three indicator data of energy efficiency, average power of charge and average power of discharge to obtain the reduced characteristic data set; then the server may perform clustering analysis on the reduced characteristic data set with the fuzzy clustering algorithm, so as to classify the battery pack.

The battery classification method provided by the embodiments of the present disclosure is more scientific for the characteristic data set of the battery pack to be classified including any combination of the following characteristic data: the charge ohmic resistance, discharge ohmic resistance, energy efficiency, average power of charge, average power of discharge, polarization voltage, temperature, maximum charge power and maximum discharge power of each single battery in the battery pack.

Alternatively, on the basis of the embodiments above, reducing the characteristic data set with rough set theory to obtain the reduced characteristic data set of the battery pack includes:

processing the characteristic data set according to the rough set theory to obtain a weight of each characteristic data of the characteristic data set;

screening the characteristic data set according to the weight of each characteristic data of the characteristic data set to obtain the reduced characteristic data set of the battery pack.

The server reducing the characteristic data set of the battery pack to be classified with the rough set theory to obtain the reduced characteristic data set of the battery pack to be classified in the embodiments above may specifically include the following process.

Firstly, the server may process the characteristic data set according to the rough set theory to obtain the weight of each characteristic data of the characteristic data set. The technical solutions of the embodiments of the present disclosure is described in detail by taking the battery pack composed of 24 lithium iron phosphate batteries in the embodiments above as an example.

FIG. 5 is a distribution chart of the battery attribute weights of the lithium iron phosphate battery pack provided by an embodiment of the present disclosure. The server can obtain the weight of each characteristic data of the characteristic data set by processing the characteristic data set of the battery pack composed of 24 lithium iron phosphate batteries with the rough set theory.

As shown in FIG. 5, energy efficiency η has the highest weight, followed by polarization voltage Up and maximum discharge power Pdh, and the weights of other characteristic data are 0, which shows that energy efficiency η, polarization voltage Up, and maximum discharge power Pdh are more important than other characteristic data.

The server can remove other characteristic data and only keep the characteristic data corresponding to the energy efficiency η, polarization voltage Up and maximum discharge power Pdh of the 24 lithium iron phosphate batteries, so as to obtain the reduced characteristic data set.

Further, the server may classify the reduced characteristic data set with the existing fuzzy clustering algorithm. For example, it can be set during initialization that the battery classification number C=4, the fuzzy weight index m=2, and the termination condition is that the number of iteration is 100 or the threshold ϵ=0.00001. When the termination condition is met, the server can classify the 24 lithium iron phosphate batteries into 4 categories.

FIG. 6 is a fuzzy clustering distribution diagram of the lithium iron phosphate battery pack provided by an embodiment of the present disclosure. As shown in FIG. 6, among the 24 lithium iron phosphate batteries, the 1st, 2nd, 3rd, 4th, 5th, 6th, 7th, 11th, 13th, 14th and 15th batteries are classified into the 1st category; the 21st battery is classified into the 2nd category; the 8th and 22nd batteries are classified into the 3rd category; and the 9th, 10th, 12th, 16th, 18th, 19th, 20th, 23rd, and 24th batteries are classified into the 4th category. The 21st battery, the 8th battery, and the 22nd battery were polarized significantly, and were sorted out separately.

This classification result is consistent with the variation of the charge and discharge voltage of the lithium iron phosphate battery pack shown in FIG. 4, which shows that it is very effective to apply the fuzzy clustering algorithm to the classification of the battery.

The battery classification method provided by the embodiments of the present disclosure is more scientific by processing the characteristic data set according to the rough set theory to obtain the weight of each characteristic data of the characteristic data set, then screening the characteristic data set according to the weight of each characteristic data of the characteristic data set to obtain the reduced characteristic data set of the battery pack.

FIG. 2 is a structural diagram of the battery classification system provided by an embodiment of the present disclosure, as shown in FIG. 2, the system includes an obtaining module 20, a reducing module 21 and a clustering module 22; it should be noted that the battery classification system also includes at least one processor and at least one memory (not shown in the drawings); the modules above are stored in the memory, and when being executed by the processor, the obtaining module 20 is configured to obtain circulatory charge and discharge data of a battery pack to be classified, extract a characteristic data set of the battery pack from the charge and discharge data; the reducing module 21 is configured to reduce the characteristic data set with rough set theory to obtain a reduced characteristic data set of the battery pack; and the clustering module 22 is configured to classify single batteries of the battery pack according to the reduced characteristic data set with fuzzy clustering algorithm.

Currently, most of the lithium iron phosphate batteries widely used in the field of electric vehicles are connected in series or in parallel by dozens to form a unit module. Whereby, several batteries can reach higher voltages in series so as to drive the motor. Taking 24 100 Ah retired battery packs of a certain model as an example, a charge and discharge test with 0.3 C magnification is conducted, and the test curve is shown in FIG. 4.

It can be seen from FIG. 4 that the voltage discreteness of the 24 lithium iron phosphate batteries is large in the charge and discharge process. The lithium iron phosphate battery with the worst condition reaches the charge and discharge cutoff voltage threshold first, and the charge and discharge curves of several lithium iron phosphate batteries were quite close. It will be difficult to reasonably classify the above-mentioned 24 lithium iron phosphate batteries at a time based on the charge and discharge curve only without special processing.

The battery classification system provided by the embodiments of the present disclosure may include the obtaining module 20, the reducing module 21 and the clustering module 22.

The obtaining module 20 may obtain the circulatory charge and discharge data of the battery pack to be classified, and extract the characteristic data set of the battery pack from the charge and discharge data. For example, the battery pack to be classified includes 24 lithium iron phosphate batteries. The obtaining module 20 may obtain the 0.3 C circulatory charge and discharge data of the 24 lithium iron phosphate batteries, and extract the indicator data characterizing the battery characteristics of the 24 lithium iron phosphate batteries from the 0.3 C circulatory charge and discharge data, so as to form the characteristic data set.

The reducing module 21 may reduce the characteristic data set with existing rough set theory, and remove the unimportant indicator data in the characteristic data set, so as to obtain the reduced characteristic data set of the battery pack to be classified.

The clustering module 22 may perform clustering analysis on the reduced characteristic data set, and classify the single batteries of the battery pack with the existing fuzzy clustering algorithm.

The functions of the battery classification system provided by the embodiments of the present disclosure may specifically refer to the method embodiments above, which will not be repeated herein.

The battery classification system provided by the embodiments of the present disclosure can be applied to the retired power batteries, and improves the efficiency of classifying the retired power batteries by obtaining the circulatory charge and discharge data of the battery pack to be classified, extracting the characteristic data set of the battery pack from the charge and discharge data, reducing the characteristic data set with rough set theory to obtain the reduced characteristic data set of the battery pack, and classifying single batteries of the battery pack according to the reduced characteristic data set with fuzzy clustering algorithm.

Alternatively, on the basis of the embodiments above, the obtaining module is specifically configured to extract from the charge and discharge data any combination of the following characteristic data: the charge ohmic resistance, discharge ohmic resistance, energy efficiency, average power of charge, average power of discharge, polarization voltage, temperature, maximum charge power and maximum discharge power of each single battery in the battery pack to be classified.

The obtaining module of the embodiments above can extract from the charge and discharge data any combination of the following characteristic data: the charge ohmic resistance, discharge ohmic resistance, energy efficiency, average power of charge, average power of discharge, polarization voltage, temperature, maximum charge power and maximum discharge power of each single battery in the battery pack to be classified.

The technical solutions of the embodiments of the present disclosure will be described in detail hereinafter by taking the battery pack composed of 24 lithium iron phosphate batteries as an example.

The obtaining module may extract the characteristic data set of the 24 lithium iron phosphate batteries from the 0.3 C circulatory charge and discharge data of the battery pack composed of 24 lithium iron phosphate batteries, wherein the characteristic data set may include 8 indicator data of each of the 24 lithium iron phosphate batteries, which are respectively: charge ohmic resistance, discharge ohmic resistance, energy efficiency, average power of charge, average power of discharge, polarization voltage, maximum charge power and maximum discharge power.

Wherein the charge ohmic resistance may be denoted as Rc, the discharge ohmic resistance may be denoted as Rd, the energy efficiency may be denoted as η, the average power of charge may be denoted as Pca, the average power of discharge may be denoted as Pda, the polarization voltage may be denoted as Up, the maximum charge power may be denoted as Pch, and the maximum discharge power may be denoted as Pdh. The characteristic data set of the battery pack composed of 24 lithium iron phosphate batteries is shown in table I, wherein the number of each single battery in the 24 lithium iron phosphate batteries is ranked from 1 to 24 in sequence.

After the obtaining module extracts the characteristic data set of the battery pack to be classified, the reducing module may reduce the characteristic data set with the rough set theory, and remove the unimportant indicator data in the characteristic data set, so as to obtain the reduced characteristic data set of the battery pack to be classified. For example, if three indicator data of energy efficiency, average power of charge and average power of discharge are found to have few influence or no influence on battery classification when the reducing module is reducing the characteristic data set with the rough set theory, the reducing module may remove the three indicator data of energy efficiency, average power of charge and average power of discharge of the battery pack to be classified to obtain the reduced characteristic data set; then the clustering module may classify the battery pack to be classified according to the reduced characteristic data set with the fuzzy clustering algorithm.

The battery classification system provided by the embodiments of the present disclosure is more scientific for the characteristic data set of the battery pack to be classified including any combination of the following characteristic data: the charge ohmic resistance, discharge ohmic resistance, energy efficiency, average power of charge, average power of discharge, polarization voltage, temperature, maximum charge power and maximum discharge power of each single battery in the battery pack.

Alternatively, on the basis of the embodiments above, the obtaining module includes a weighting sub module and a reducing sub module; wherein

the weighting sub module is configured to process the characteristic data set according to the rough set theory to obtain a weight of each characteristic data of the characteristic data set; the reducing sub module is configured to screen the characteristic data set according to the weight of each characteristic data of the characteristic data set to obtain the reduced characteristic data set of the battery pack.

Specifically, the reducing module of the embodiments above may include a weighting sub module and a reducing sub module.

The weighting sub module may process the characteristic data set according to the rough set theory to obtain the weight of each characteristic data of the characteristic data set. The technical solutions of the embodiments of the present disclosure is described in detail by taking the battery pack composed of 24 lithium iron phosphate batteries in the embodiments above as an example. The weighting sub module can obtain the weight of each characteristic data of the characteristic data set by processing the characteristic data set of the battery pack composed of 24 lithium iron phosphate batteries with the rough set theory.

As shown in FIG. 5, energy efficiency η has the highest weight, followed by polarization voltage Up and maximum discharge power Pdh, and the weights of other characteristic data are 0, which shows that energy efficiency η, polarization voltage Up, and maximum discharge power Pdh are more important than other characteristic data.

The reducing sub module can remove other characteristic data and only keep the characteristic data corresponding to the energy efficiency η, polarization voltage Up and maximum discharge power Pdh of the 24 lithium iron phosphate batteries, so as to obtain the reduced characteristic data set.

The clustering module may classify the reduced characteristic data set with the existing fuzzy clustering algorithm. For example, it can be set during initialization that the battery classification number C=4, the fuzzy weight index m=2, and the termination condition is that the number of iteration is 100 or the threshold ϵ=0.00001. When the termination condition is met, the clustering module can classify the 24 lithium iron phosphate batteries into 4 categories.

As shown in FIG. 6, among the 24 lithium iron phosphate batteries, the 1st, 2nd, 3rd, 4th, 5th, 6th, 7th, 11th, 13th, 14th and 15th batteries are classified into the 1st category; the 21st battery is classified into the 2nd category; the 8th and 22nd batteries are classified into the 3rd category; and the 9th, 10th, 12th, 16th, 18th, 19th, 20th, 23rd, and 24th batteries are classified into the 4th category. The 21st battery, the 8th battery, and the 22nd battery were polarized significantly, and were sorted out separately.

The battery classification method provided by the embodiments of the present disclosure is more scientific by processing the characteristic data set according to the rough set theory to obtain the weight of each characteristic data of the characteristic data set, then screening the characteristic data set according to the weight of each characteristic data of the characteristic data set to obtain the reduced characteristic data set of the battery pack.

FIG. 3 is a structural diagram of the electronic device provided by an embodiment of the present disclosure, as shown in FIG. 3, the electronic device may include a processor 31, a memory 32 and a bus 33, wherein

the processor 31 and the memory 32 communicate with each other through the bus 33; the processor 31 is configured to call the program instructions in the memory 32 to execute the methods provided by each method embodiment above, including, for example, obtaining circulatory charge and discharge data of a battery pack to be classified, extracting a characteristic data set of the battery pack from the charge and discharge data; reducing the characteristic data set with rough set theory to obtain a reduced characteristic data set of the battery pack; classifying single batteries of the battery pack according to the reduced characteristic data set with fuzzy clustering algorithm.

An embodiment of the present disclosure provides a computer program product including computer programs stored in a non-transitory computer readable storage medium, the computer program including program instructions, when executed by a computer, the computer is able to execute the methods provided by each method embodiment above, including, for example, obtaining circulatory charge and discharge data of a battery pack to be classified, extracting a characteristic data set of the battery pack from the charge and discharge data; reducing the characteristic data set with rough set theory to obtain a reduced characteristic data set of the battery pack; classifying single batteries of the battery pack according to the reduced characteristic data set with fuzzy clustering algorithm.

An embodiment of the present disclosure provides a non-transitory computer readable storage medium, which stores computer instructions instructing a computer to execute the methods provided by each method embodiment above, including, for example, obtaining circulatory charge and discharge data of a battery pack to be classified, extracting a characteristic data set of the battery pack from the charge and discharge data; reducing the characteristic data set with rough set theory to obtain a reduced characteristic data set of the battery pack; classifying single batteries of the battery pack according to the reduced characteristic data set with fuzzy clustering algorithm.

The embodiments such as the electronic device described above are only illustrative, in which the units described as separate parts may or may not be physically separated, and the parts displayed as units may or may not be physical units, that is, they may be located in one place, or may also be distributed to multiple network units. According to actual needs, some or all of the modules may be selected to achieve the objects of the solutions of the embodiments. Those of ordinary skill in the art can understand and implement without creative work.

Through the description of the embodiments above, those skilled in the art can clearly understand that each embodiment can be implemented by means of software with necessary universal hardware platform, and can also, of course, by means of hardware. Based on such understanding, the technical solutions of the present disclosure, or the part thereof contributing to the prior art, or parts thereof can be embodied in the form of a software product stored in a storage medium, such as ROM/RAM, magnetic disk, optical disk, etc., the software product includes certain instructions so that a computer device (may be a personal computer, a server, or a network device, etc.) performs the methods described in each of the embodiments, or some parts of the embodiments.

Finally, it should be noted that each embodiment above is only used to illustrate rather than to limit the technical solutions of the embodiments of the present disclosure; although the present disclosure has been described in detail with reference to the foregoing embodiments, those of ordinary skill in the art should understand that they can still modify the technical solutions described in the foregoing embodiments, or equivalently replace some or all of the technical features therein; and these modifications or replacements do not separate the essence of the corresponding technical solutions from the spirit and scope of the technical solutions of each of the embodiments of the present disclosure.

1. A battery classification method, comprising:
obtaining circulatory charge and discharge data of a battery pack to be classified, extracting a characteristic data set of the battery pack from the charge and discharge data;
reducing the characteristic data set with rough set theory to obtain a reduced characteristic data set of the battery pack;
classifying single batteries of the battery pack according to the reduced characteristic data set with fuzzy clustering algorithm.

2. The method of claim 1, wherein the characteristic data set comprises any combination of following characteristic data: charge ohmic resistance, discharge ohmic resistance, energy efficiency, average power of charge, average power of discharge, polarization voltage, temperature, maximum charge power and maximum discharge power of each single battery in the battery pack.

3. The method of claim 1, wherein reducing the characteristic data set with the rough set theory to obtain the reduced characteristic data set of the battery pack comprises:
processing the characteristic data set according to the rough set theory to obtain a weight of each characteristic data of the characteristic data set;
screening the characteristic data set according to the weight of each characteristic data of the characteristic data set to obtain the reduced characteristic data set of the battery pack.

4. A battery classification system, comprising:
at least one processor; at least one memory; an obtaining module, a reducing module and a clustering module stored in the memory, when being executed by the processor,
the obtaining module is configured to obtain circulatory charge and discharge data of a battery pack to be classified, extract a characteristic data set of the battery pack from the charge and discharge data;
the reducing module is configured to reduce the characteristic data set with rough set theory to obtain a reduced characteristic data set of the battery pack;
the clustering module is configured to classify single batteries of the battery pack according to the reduced characteristic data set with fuzzy clustering algorithm.

5. The system of claim 4, wherein the obtaining module is specifically configured to:
extract from the charge and discharge data any combination of following characteristic data: charge ohmic resistance, discharge ohmic resistance, energy efficiency, average power of charge, average power of discharge, polarization voltage, temperature, maximum charge power and maximum discharge power of each single battery in the battery pack.

6. The system of claim 4, wherein the reducing module comprises:
a weighting sub module configured to process the characteristic data set according to the rough set theory to obtain a weight of each characteristic data of the characteristic data set;
a reducing sub module configured to screen the characteristic data set according to the weight of each characteristic data of the characteristic data set to obtain the reduced characteristic data set of the battery pack.

7. A computer readable storage medium, in which computer programs are stored, wherein the method of claim 1 is implemented when a processor executes the computer programs.
